(19) United States
(12) Patent Application Publication
(10) Pub. No.: US 2002/0070045 A1
(43) Pub. Date: Jun. 13, 2002

(54) Interconnect system for electronic packages

(76) Inventors: Robert W. Musk, Kingsbridge (GB); Adrian Kendall, Ipswich (GB); David Savage, Plymouth (GB)

Correspondence Address: LACASSE & ASSOCIATES, LLC, 1725 DUKE STREET, SUITE 650, ALEXANDRIA, VA, 22314, US

(21) Appl. No.: 09/733,972

(22) Filed: Dec. 12, 2000

(51) Int. Cl. H01L 23/02

(52) U.S. Cl. 174/52.4

(57) ABSTRACT

An interconnect system for a butterfly package e.g. a laser package is provided on at least one feedthrough wall of the package through which extends a plurality of electrical connectors. A ceramic or glass circuit block is disposed on the inner side of the wall or of a feedthrough insert. The circuit block has an insulating surface and an electrical circuit disposed on said surface, the circuit being in electrical connection with at least some of the electrical connectors. The block abuts the electrical connectors on the inner side of the feedthrough wall to provide a support for the connectors.

### FIELD OF THE INVENTION

This invention relates to packaging for electronic devices and more particularly to an interconnect system for packages for electronic devices such as lasers, chips and electrical circuits.

### BACKGROUND OF THE INVENTION

It is known that electronic or optical devices should not operate in environments hostile to their reliable operation. It is desirable to place one or more of such devices in a hermetic package that is sealed from dust, humidity and gaseous contaminants. When such a device is thus sealed inside the package, electrical connectors must be provided from the outside of the package to the device placed inside. Typically, for economic reasons, the envelope of the package is made of a metal or an alloy, thus the connectors must be fed through insulating feedthroughs. However, other materials can also be used for the packaging envelopes e.g. various ceramics or metal matrix composites.

Electronic devices inside the package may have numerous electrical connections that must be made through the packaging material. If the package is made of a conductive material such as metal or metal matrix composite, each electrical connection through the package must be insulated from the packaging material to prevent electrical shorting to the envelope. Of course, for the package to be hermetic, each passageway (feedthrough) of the connection through the envelope of the package must also be hermetically sealed.

The electrical connections are desirably sturdy enough to be self-supporting so that they rigidly extend from both sides of a package forming e.g. a well-known “butterfly” configuration wherein the connectors or leads exit symmetrically through the package sidewalls. However, this creates a situation wherein a large number of leads, combined with a tendency to miniaturize the size of the entire package, may limit the space between the connections and impair the quality of insulation therebetween. On the other hand, if the electrical connections (or “pins”) are of smaller cross-section, they may be prone to distortion or damage during assembly, and some form of mechanical support may be desirable.

The insulating material for the feedthroughs for the electrical connections is usually glass or ceramic. A common solution is to employ a MLC (multilayer ceramic) insert or structure as taught e.g. in U.S. Pat. No. 5,221,860 to Dietrich et al. or U.S. Pat. No. 5,434,358 to Glahn et al. The MLC structure is typically brazed to the metallic wall of the package. External electrical connections may be provided through the use of a leadframe that is brazed to a metallization on the ceramic structure or insert. Electrical connections to the inner package are effected through the printed ceramic or a MLC that may be created in several layers to achieve the correct level of interconnect. Leads may also be brazed to the inner side of the ceramic structure or the MLC insert for welded connections.

An alternative to a ceramic or MLC insert is to use conventional glass-to-metal seal technology that provides both the inner and the outer electrical connection together with the hermetic seal in one operation. It is noted that U.S. Pat. No. 5,940,279 to Gademann et al. proposes a separate pin block made of Kovar, with the connector pins glass-mounted into the pin block.

There are many instances where the internal connections of the electronic or photoelectronic element e.g. laser do not match the geometric locations of the electrical connector pins. In such a case, it is desirable to provide a low-cost means for routing connections to the correct pins.

It is also desirable to provide a low-cost electrical interconnect system for packages for optoelectronic and other devices.

### SUMMARY OF THE INVENTION

In accordance with the invention, there is provided an interconnect system suitable for an electronic package for an electronic or optoelectronic element, the package having at least one wall (feedthrough wall) for guiding electrical connection therethrough. The interconnect system comprises a barrier fastened to the at least one feedthrough wall of the package, the barrier having an inner side and an outer side, a plurality of electrical connectors extending through the barrier between the inner side of the barrier and the outer side thereof, and a circuit block disposed on the inner side of the barrier.

The term “barrier” encompasses both an integral part of the feedthrough wall and a separate, e.g. insert-type structure mounted to the wall, e.g. a glass-metal seal.

The circuit block comprises an insulating surface and an electrical circuit disposed on said surface, the circuit being in electrical connection with at least some of the electrical connectors, typically pins.

The block may abut at least some of the pins on the inner side of the barrier thus functioning as a support for these pins. This may facilitate wire bonding and other operations inside the package. The block may be made of a ceramic or another convenient insulating material e.g. glass.

In an embodiment of the invention, the block is made of a suitable ceramic material and has a plurality of cutouts or notches of a shape adapted to accommodate the shape of the connector pins, the spacing of the cutouts corresponding to the spacing of the connector pins.

The barrier may be made of any suitable material or a combination of materials, provided that it has insulating feedthroughs or passages for the electrical connectors.

### BRIEF DESCRIPTION OF THE DRAWINGS

The invention will be explained in more detail by way of the following description to be taken in association with the drawings in which:

FIG. 1 is a perspective view of a butterfly package having an interconnect system according to the invention,

FIG. 2 is a partial cross-sectional view of the interconnect system,

FIGS. 3a-3c illustrate the preparation of an exemplary circuit block

### DETAILED DESCRIPTION OF THE INVENTION

As will be clear from the following description, the term “circuit block” denotes any suitable solid formation, e.g. a thin plate, less than 1 mm thick. The block may be integral with a feedthrough wall of the package or a feedthrough insert therein, permanently attached or releasably attached to the electrical connectors, to the insert or to the wall.

The term “feedthrough wall” denotes one or more walls of the package containing passages for the electrical connections of the electronic/optoelectronic element housed inside the package.

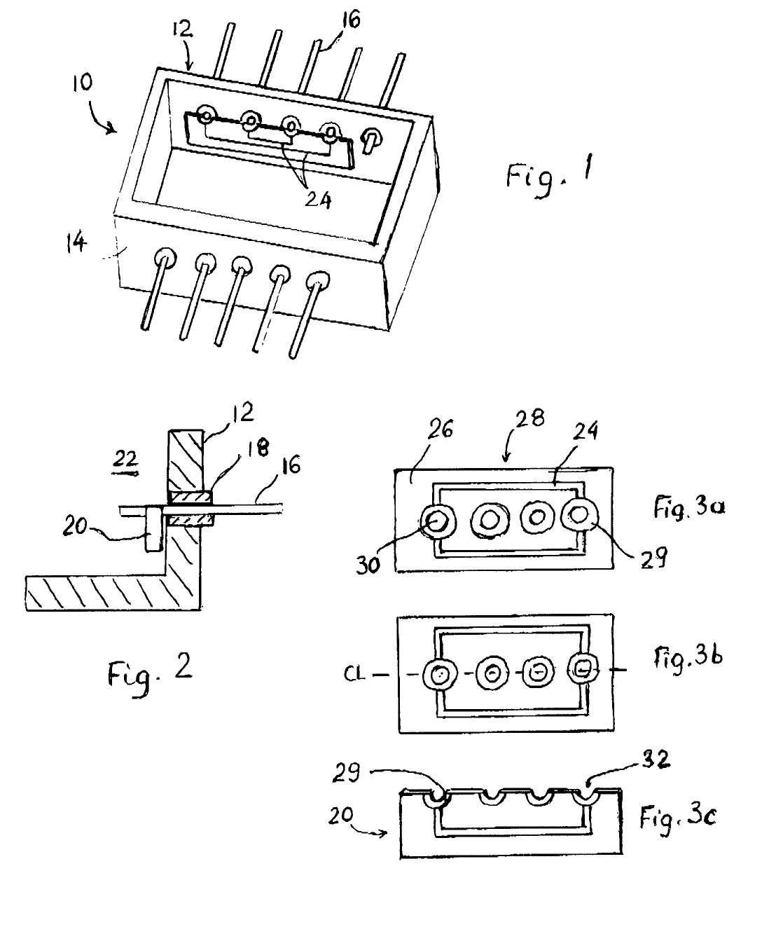

Turning now to FIG. 1 and FIG. 2, a laser butterfly package is generally represented as 10. The package has two opposite feedthrough walls 12, 14. Connector pins 16 are shown embedded in glass seals 18 disposed concentrically around the respective pins in the walls 12, 14. A ceramic block 20 is brazed to the pins on the inside, laser side 22 of the package.. As shown in FIG. 1 and FIGS. 3a-3c, the block 20 has an electric circuit 24 printed on the insulating surface 26 of the block in a conventional manner. Alternatively, the block may be fastened to the wall 12 by means of an adhesive provided of course that the circuit disposed thereon is in electrical contact with at least some of the pins 16. The package 10 houses a laser, not shown, disposed on its bottom surface.

FIGS. 3a-3c illustrate an exemplary method of making the block 20. A conventional thick film ceramic (96-99% Al₂O₃) plate 28 of a thickness approximately 0.025″ is provided with a series of holes 30 that match the pitch of the pins of the package, approximately 0.1 in. The ceramic plate 28 is screen printed with a suitable metal 29 that is also partly drawn down into the holes 30 to metallize a portion of the inner surfaces of the holes. The screen printing process also allows interconnection between different pins to be achieved by printing tracks. Electrical crossover can be accomplished by using conventional thick film dielectric crossover structures, well known in the art. Once the ceramic structure has been printed and fired (FIG. 3a), it is scribed and broken, using laser cutting, scribing techniques or another approach), along the centerline CL of the holes (FIG. 3b). The half-hole section (FIG. 3c) featuring cutouts 32 of a shape and spacing adapted to the shape and spacing of the pins 16 is then fitted to the pins on the inside of the package 10 using suitable soldering or brazing techniques.

It will be understood that the halving above described is not the only method of making a block of the invention, and is merely advantageous for its efficiency and simplicity. Alternatively, a glass plate or block may be used as a substitute for the ceramic block 20.

As is best seen in FIG. 2, the block 20 may function as a mechanical support for the internal segments of the pins 16 which is advantageous in wire bonding of the leads and other assembly operations.

The above-described package may be rendered hermetic by sealing with a conventional cap.

The above-described embodiment of the interconnect system and a method of its manufacturing are merely exemplary and the scope of the invention is to be defined only by the appended claims when accorded a full range of equivalence, many modifications and variations naturally occurring to those skilled in the art.

1. In a package for an electronic or optoelectronic element, the package having at least one feedthrough wall for guiding electrical connection therethrough, an interconnect system comprising:
a barrier fastened to the at least one feedthrough wall of the package, the barrier having an inner side and an outer side,
a plurality of electrical connectors extending through the barrier between the inner side of the barrier and the outer side thereof, and
a circuit block disposed on the inner side of the barrier, the circuit block comprising
an insulating surface and an electrical circuit disposed on said surface, the circuit being in electrical connection with at least some of the electrical connectors.

2. The system according to claim 1 wherein said block abuts at least some of the electrical connectors on the inner side of the barrier to provide a support for the connectors.

3. The system according to claim 1 wherein said block is of a ceramic material.

4. The system according to claim 1 wherein said block has a plurality of cutouts shaped and spaced to accommodate the shape and spacing of said electrical connectors respectively.

5. The system according to claim 1 wherein said package is a butterfly package.

6. The system according to claim 4 wherein said cutouts have metallized regions.

7. The system according to claim 6 wherein said cutouts are attached to at least some of the electrical connectors by way of the metallized regions.

8. The system according to claim 1 wherein said barrier comprises glass insulators surrounding said pins.

9. The system according to claim 1 wherein said block is of glass.

10. A circuit block for an electrical interconnect system having a plurality of interspaced electrical connectors, the circuit block comprising
a body having an insulating surface, and
an electrical circuit disposed on said insulating surface,
the electrical circuit disposed to contact at least some of said electrical connectors when said block is placed adjacent to the connectors.

11. The block according to claim 10 wherein said block has cutouts spaced in accordance with the spacing of the electrical connectors.
